(19) United States
(12) Patent Application Publication
(10) Pub. No.: US 2013/0239993 A1
(43) Pub. Date: Sep. 19, 2013

(54) FILM-FORMING APPARATUS AND METHOD FOR CLEANING FILM-FORMING APPARATUS

(71) Applicants: Yohei Ogawa, Susono-shi (JP); Satoru Toyoda, Susono-shi (JP); Yoshihiro Okamura, Susono-shi (JP)

(72) Inventors: Yohei Ogawa, Susono-shi (JP); Satoru Toyoda, Susono-shi (JP); Yoshihiro Okamura, Susono-shi (JP)

(73) Assignee: ULVAC, INC., Chigasaki-shi, Kanagawa (JP)

(21) Appl. No.: 13/988,411

(22) PCT Filed: Nov. 22, 2011
(86) PCT No.: PCT/JP11/76883

§ 371 Date: May 20, 2013

(30) Foreign Application Priority Data
Nov. 24, 2010 (JP) 2010-260896

(51) Int. Cl. C23C 16/44

(52) U.S. Cl. CPC C23C 16/4405
USPC 134/19; 118/715; 118/733

(57) ABSTRACT

A film-forming apparatus includes a heat generator exposed to a film-forming gas drawn into a chamber to generate film formation species. A film-forming gas supply system supplies the film-forming gas into the chamber. A control unit sets the heat generator in a non-heated state during a cleaning process that discharges a film formation residue from the chamber. A cleaning gas supplying system supplies a cleaning gas including ClF3 into the chamber. A temperature adjustment unit adjusts the chamber to a target temperature from 100° C. or higher to 200° C. or less in the cleaning process. A discharge system discharges a reaction product produced by a reaction between the film formation residue and the cleaning gas from the chamber.

### TECHNICAL FIELD

The present invention relates to a film-forming apparatus and a method for cleaning a film-forming apparatus.

### BACKGROUND ART

Chemical vapor deposition (CVD), which is a technique for forming thin films on a substrate using chemical reaction, includes plasma CVD, thermal CVD, hot wire CVD, and catalytic CVD. Hot wire CVD and catalytic CVD use a heated metal wire such as tungsten, which is arranged exposed to a source gas to decompose the gas and generate film formation species. Hot wire CVD and catalytic CVD significantly reduce electric damage and thermal damage on the substrate or on the underlying layers.

In continuous film formation performed by CVD, the chemical reaction for forming a film is repeated in the film-forming chamber. The film formation species can partially reside and accumulate in the film-forming chamber. Such film formation residue accumulating in the film-forming chamber may defoliate from the wall surfaces and form particles that contaminate thin films. This may lower the yield or generate process variations. To prevent this, the CVD apparatus undergoes regular cleaning by supplying a cleaning gas containing active species, such as halogen, into the film-forming chamber and chemically removing the film formation residues. This method allows for continuous deposition since the film-forming chamber is not exposed to air after cleaning.

However, when the hot wire CVD apparatus or the catalytic CVD apparatus uses this cleaning method, the cleaning gas may corrode and decrease the diameter of the wire functioning as a catalyst. When the corroded catalyst wire is replaced, the film-forming chamber is exposed to air. Whenever the catalyst wire is replaced, exposure of the film-forming chamber to air significantly changes the degree of vacuum as well as the temperature in the film-forming chamber. This lengthens the maintenance time of the apparatus.

Patent literature 1 describes heating a heat generator, which corresponds to the catalyst wire, and maintaining the heat generator at 2000° C. or higher to reduce reaction between the cleaning gas and the catalyst wire.

Patent literature 2 describes moving the catalyst wire out of the film-forming chamber.

### PRIOR ART LITERATURES

### Patent Literatures

Patent Literature 1: U.S. Pat. No. 4,459,329

Patent Literature 2: Japanese Laid-Open Patent Publication No. 2009-108390

### SUMMARY OF THE INVENTION

### Problems that are to be Solved by the Invention

However, the method described in patent literature 1, which heats the heat generator corresponding to the catalyst wire at a high temperature of 2000° C. or higher, may diffuse metal atoms or impurities from the catalyst wire into thin films formed in the film formation process.

The method described in patent literature 2 complicates the apparatus. Further, when a moving unit is arranged above the substrate to move the catalyst, this may produce particles or cause process variations.

To solve the above problems, it is an object of the present invention to provide a film-forming apparatus and a method for cleaning a film-forming apparatus that reduce corrosion of a heat generator without lowering the yield.

It is another object of the present invention to provide a film-forming apparatus and a method for cleaning a film-forming apparatus that reduce corrosion of a heat generator without complicating the apparatus.

### Means for Solving the Problems

A first aspect of the present invention is a film-forming apparatus including a heat generator exposed to a film-forming gas drawn into a chamber to generate film formation species. The apparatus includes a film-forming gas supply system that supplies the film-forming gas into the chamber, a control unit that sets the heat generator in a non-heated state during a cleaning process that discharges a film formation residue from the chamber, a cleaning gas supplying system that supplies a cleaning gas including ClF₃ into the chamber, a temperature adjustment unit that adjusts the chamber to a target temperature from 100° C. or higher to 200° C. or less in the cleaning process, and a discharge system that discharges a reaction product produced by a reaction between the film formation residue and the cleaning gas from the chamber.

This structure sets the heat generator in a non-heated state during cleaning, and thus reduces corrosion of the heat generator caused by the cleaning gas. In other words, this structure adjusts the chamber to the above temperature range to allow the cleaning gas to thermally decompose in a spontaneous manner without absorbing heat from the heat generator. Thus, there is no need to subject the heat generator to a high temperature that would diffuse atoms from the heat generator. This prevents atoms from being diffused from the heat generator as impurities that contaminate thin films. This structure reduces corrosion of the heat generator in the cleaning process while preventing the yield from decreasing. Although the heat generator is set in a non-heated state in the cleaning process, adjustment of the temperature in the chamber enables cleaning to be performed while reducing corrosion of the heat generator. This eliminates the need for a mechanism that moves the heat generator, and prevents the apparatus from being complicated.

Preferably, the temperature adjustment unit includes a temperature adjustment mechanism that uses a heat medium having a boiling point higher than or equal to the target temperature to exchange heat between the heat medium and the chamber. The temperature adjustment mechanism includes a cooling unit, which cools the heat medium in a film formation process, and a heating unit, which heats the heat medium in a cleaning process when the heat medium has a lower temperature than the target temperature.

This structure integrates the cooling mechanism for cooling the chamber and the heating mechanism for heating the chamber. Thus, enlargement of the apparatus is avoided.

Preferably, the film-forming gas supply system supplies the film-forming gas to form a thin film, which includes at least one of TiN, TaN, WF₆, HfCl₄, Ti, Ta, Tr, Pt, Ru, Si, SiN, SiC, and Ge, or to form an organic thin film.

This structure efficiently removes film formation residues formed by the film-forming apparatus by using the cleaning gas including ClF₃and adjusting the temperature in the chamber to the target temperature.

Preferably, the film-forming apparatus further includes a seal that hermetically seals the chamber. The seal is formed from a perfluoro rubber or perfluoroelastomer.

In this structure uses, the seal for sealing the chamber is resistant to corrosion caused by ClF₃, which is included in the cleaning gas, and resistant to the heat in the chamber that is adjusted to a temperature from 100° C. or higher to 200° C. or less. This prevents corrosion of the seal in the cleaning process, and provides optimum seal.

A second aspect of the present invention is a method for cleaning a film-forming apparatus, wherein the film-forming apparatus performs a film formation process for exposing a heat generator arranged in a chamber to a film-forming gas to generate film formation species and form a thin film on a substrate and then performs a cleaning process to remove a film formation residue from the chamber. The method includes setting the heat generator in a non-heated state, adjusting the chamber to a target temperature from 100° C. or higher to 200° C. or lower, and supplying a cleaning gas including ClF₃ into the chamber so that the cleaning gas reacts with the film formation residue in the chamber and discharging a reaction product produced by a reaction between the cleaning gas and the film formation residue.

This method sets the heat generator in a non-heated state during cleaning, and thus reduces corrosion of the heat generator caused by the cleaning gas. In other words, this method adjusts the temperature in the chamber to the above temperature range so that the cleaning gas thermally decomposes in a spontaneous manner without absorbing heat from the heat generator, and there is no need to heat the heat generator to a high temperature that would diffuse atoms from the heat generator. This prevents the heat generator from diffusing atoms as impurities that would contaminate thin films. Accordingly, corrosion of the heat generator in the cleaning process is reduced while preventing a decrease in the yield. Although the heat generator is in a non-heated state in the cleaning process, the temperature in the chamber is adjusted so that cleaning is performed while reducing corrosion of the heat generator. This eliminates the need for a mechanism that moves the heat generator, and prevents the apparatus from being complicated.

### BRIEF DESCRIPTION OF THE DRAWINGS

FIG. 1 is a schematic view of a catalytic CVD apparatus;

FIG. 2 is a schematic view of a temperature adjustment mechanism arranged in the catalytic CVD apparatus;

FIG. 3 is a graph showing weight changes of various rubbers when exposed to ClF₃ gas;

FIG. 4 is a graph showing the temperature dependency of the rate of etching by ClF₃ gas;

FIG. 5 is a graph showing voltage changes of catalyst wires before and after a cleaning process; and

FIG. 6 is a table showing the temperature dependency of the rate of etching with ClF₃ gas.

### EMBODIMENTS OF THE INVENTION

### First Embodiment

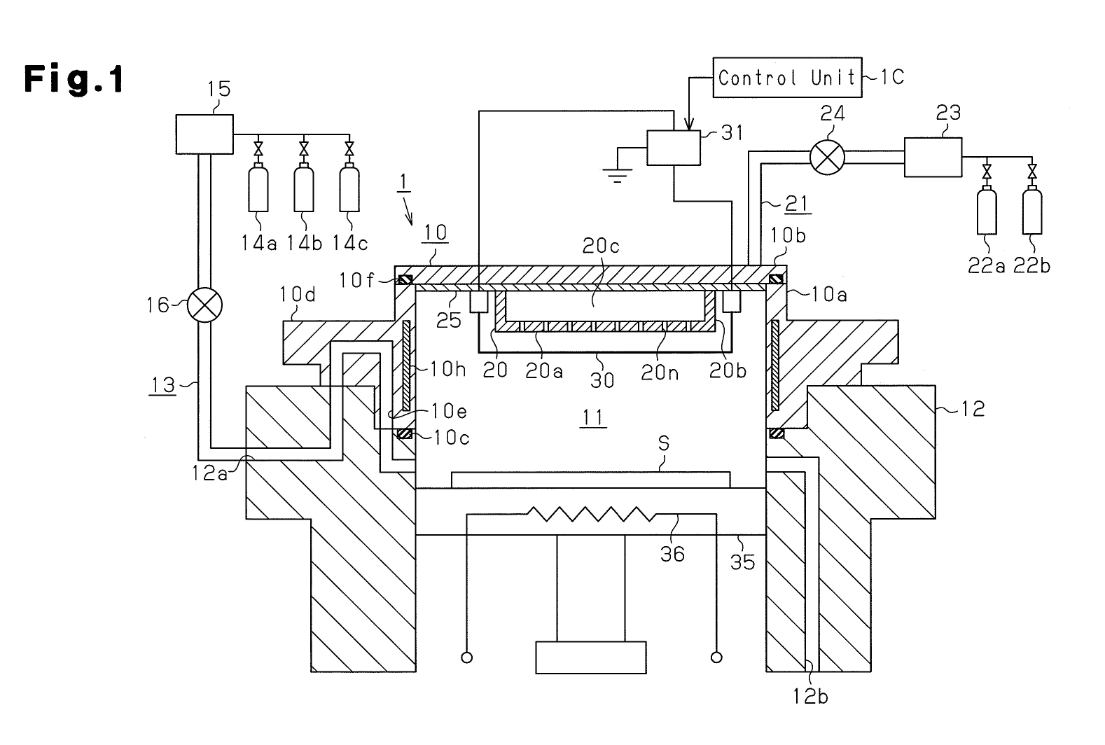

One embodiment of the present invention will now be described with reference to FIGS. 1 to 6.

As shown in FIG. 1, a film-forming apparatus 1 is a catalytic chemical vapor deposition (CVD) apparatus, and includes a chamber 10, which forms an internal film-forming chamber 11. The chamber 10 includes a tubular chamber body 10a and a lid 10b covering the upper opening of the chamber body 10a. The chamber 10 further includes a seal 10f, which is arranged between the lid 10b and the chamber body 10a. The seal 10f hermetically seals the film-forming chamber 11.

The chamber body 10a further includes a gas intake 10d, which draws various gases into the film-forming chamber 11. A gas supply passage 10e extends through the gas intake 10d. The chamber body 10a includes a side wall incorporating a heater 10h. The heater 10h increases the temperature of the film-forming chamber 11 through the chamber body 10a. The heater 10h is connected to a power supply (not shown). When supplied with current, the heater 10h heats the inside of the film-forming chamber 11 through the chamber body 10a.

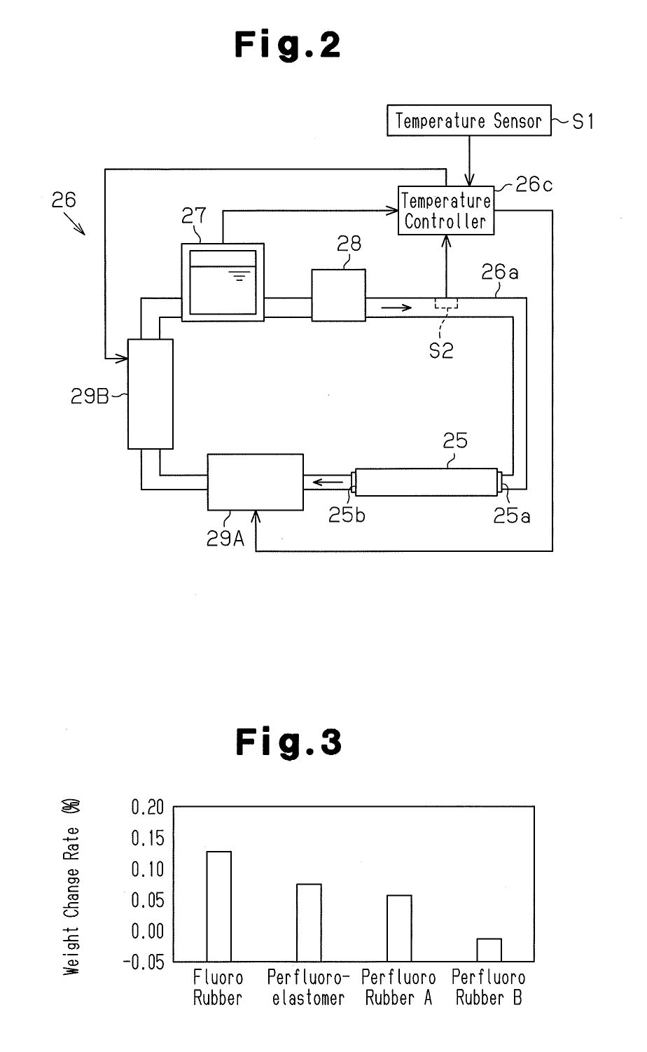

The chamber 10 accommodates a temperature sensor S1 arranged so as not to receive heat directly from the heater 10h (refer to FIG. 2). The temperature sensor S1 detects the temperature in the film-forming chamber 11.

The chamber 10 is fixed to a support member 12. An annular seal 10c is arranged between the chamber 10 and the support member 12. The seal 10c hermetically seals the inside of the film-forming chamber 11.

The support member 12 includes a gas supply passage 12a. The gas supply passage 12a is connected to the gas supply passage 10e of the chamber 10 when the chamber 10 is fixed to the support member 12.

A film-forming gas supply system 13 is connected to the gas supply passage 12a of the support member 12. The film-forming gas supply system 13 includes gas supply sources 14a to 14c, a mass flow controller 15, and a supply valve 16. The gas supply sources 14a to 14c are filled with various film-forming gases, such as titanium tetrachloride (TiCl₄) gas, ammonia (NH₃) gas, and nitrogen (N₂) gas.

The support member 12 further includes a discharge passage 12b that discharges gas out of the film-forming chamber 11. A pump, such as a turbomolecular pump (not shown), is connected to the discharge passage 12b. When the pump is driven, fluids are drawn out of and discharged from the film-forming chamber 11. The discharge passage 12b is an example of a discharge system.

The film-forming chamber 11 further accommodates a shower plate 20, which jets cleaning gas into the film-forming chamber 11. The shower plate 20 is substantially disc-shaped, and includes a bottom wall 20a and a side wall 20b surrounding the bottom wall 20a. The bottom wall 20a and the side wall 20b define an inner space that functions as a buffer 20c for temporarily storing a cleaning gas. A plurality of nozzles 20n extend through the bottom wall 20a.

The shower plate 20 is connected to a cleaning gas supply system 21, which is arranged outside the chamber 10. The cleaning gas supply system 21 includes cleaning gas supply sources 22a and 22b, a mass flow controller 23, and a supply valve 24. The cleaning gas supply sources 22a and 22b are filled with inert gases, such as chlorine trifluoride (ClF₃) gas, argon (Ar) gas, and nitrogen (N₂) gas. The inert gases are not particularly limited to the above inert gases.

The ClF₃ gas is highly corrosive. In the present embodiment, the inside of the film-forming chamber 11 is heated to about 100° C. to 200° C. in a cleaning process and a film formation process. Thus, when the ClF₃ gas is used as a cleaning gas, the seal 10c for sealing the film-forming chamber 11 is required to be corrosion resistant and heat resistant. FIG. 3 shows evaluation results for different seal materials. FIG. 3 shows the comparison between fluoro rubber, which is a conventional seal material, and a perfluoroelastomer and a perfluoro rubber, which are generally known as being corrosion resistant. Samples formed from different rubbers but having the same shape and the same size were exposed to the ClF₃ gas at a temperature of about 120° C. for two hours. Changes in the weight of each sample were measured. Two perfluoro rubbers with different compositions, or perfluoro rubbers A and B, were used. The samples formed from perfluoroelastomer and perfluoro rubbers A and B showed lower weight changes than the sample formed from fluoro rubber. Although the sample formed from perfluoroelastomer had larger weight changes than the samples formed from perfluoro rubbers A and B, the difference between these materials was subtle. Thus, it was determined that perfluoroelastomer and perfluoro rubbers A and B are both usable.

As shown in FIG. 1, a catalyst wire 30 is arranged below the shower plate 20. The catalyst wire 30 is an example of a heat generator. The catalyst wire 30 may be formed from any material and have any shape. In the present embodiment, the catalyst wire 30 is formed from tungsten, and includes two bent portions. The two ends of the catalyst wire 30 are fixed to the lid 10b of the chamber 10. The catalyst wire 30 includes a straight portion between the two bent portions. The straight portion of the catalyst wire 30 extends horizontally in an upper portion of the film-forming chamber 11. The straight portion of the catalyst wire 30 is arranged near the lower surface of the shower plate 20. The catalyst wire 30 is connected to a constant current supply 31, which is activated and deactivated by a control unit 1C. The catalyst wire 30 generates heat when supplied with current from the constant current supply 31, and reaches 1700° C. to 2000° C. in a film formation process. The catalyst wire 30 heated to such high temperatures is exposed to ammonia gas. This heats and decomposes ammonia gas and generates radical species. The radical species then react with TiCl₄ to form film formation species.

A substrate stage 35 is arranged on the bottom of the film-forming chamber 11. The substrate stage 35 includes an electrostatic chuck (not shown), which attracts a substrate S with electrostatic force. The substrate stage 35 incorporates a heater 36, which heats the substrate stage 35 to a predetermined temperature. The heater 36 and the heater 10h of the chamber 10 are energized and de-energized under control by the control unit 1C.

A temperature control plate 25 for cooling and heating the chamber 10 and the like is arranged between the shower plate 20 and the lid 10b of the chamber 10. The upper surface of the shower plate 20 is in close contact with the temperature control plate 25. The temperature control plate 25 is fixed to the lid 10b of the chamber 10. This structure enables efficient heat exchange between the temperature control plate 25 and the chamber 10 and between the temperature control plate 25 and the shower plate 20.

FIG. 2 is a schematic view of a temperature adjustment mechanism 26 including the temperature control plate 25. In addition to the temperature control plate 25 that is substantially disc-shaped, the temperature adjustment mechanism 26 includes a heat medium reservoir 27, which stores a heat medium, a pump 28, which pumps the heat medium, a first heat exchanger 29A, which cools the heat medium, a second heat exchanger 29B, which heats the heat medium, and a heat medium pipe 26a, which connects the heat medium reservoir 27, the temperature control plate 25, and other components to one another. The heat medium pipe 26a circulates the heat medium. The first heat exchanger 29A is an example of a cooling unit. The second heat exchanger 29B is an example of a heating unit.

The heat medium reservoir 27 is a liquid tank that includes an inlet, through which the heat medium flows in, and an outlet, through which the heat medium flows out. The pump 28, which is arranged in the heat medium pipe 26a, pumps the heat medium from the heat medium reservoir 27 to the temperature control plate 25. A temperature sensor S2 is arranged between the heat medium reservoir 27 and the temperature control plate 25 in the heat medium pipe 26a. The temperature sensor S2 detects the temperature of the heat medium, which is supplied to the temperature control plate 25, and outputs a temperature detection signal indicating the detected temperature to the temperature controller 26c.

The temperature control plate 25 is substantially disc-shaped to conform to the shape of the shower plate 20. The temperature control plate 25 includes a heat medium inlet port 25a and a heat medium outlet port 25b. The heat medium flows through a flow passage extending through the temperature control plate 25. The flow passage may be in any shape. In one example, the flow passage may be formed solely by a space storing the heat medium, or may include bent portions (or in a zigzag portions) formed by bending the flow passage at a plurality of positions of the temperature control plate 25.

The first heat exchanger 29A and the second heat exchanger 29B, which each exchange heat with the heat medium, are arranged between the temperature control plate 25 and the heat medium reservoir 27. The first heat exchanger 29A may have any structure. To enable heat exchange between a coolant and a heat medium, the first heat exchanger 29A may, for example, include a piping passage that allows circulation of the coolant, a compressor for compressing the gaseous coolant into a liquid, a depressurizing valve that releases the pressure of the high-pressure coolant, and an evaporator that evaporates and cools the liquid coolant.

The first heat exchanger 29A receives a feedback signal from the temperature controller 26c, which receives a temperature detection signal from the temperature sensor S2 and generates the feedback signal in accordance with the temperature detection signal. The first heat exchanger 29A adjusts the temperature of the heat medium to a target temperature based on the feedback signal. In the film formation process, for example, the temperature of the heat medium is adjusted to a film formation temperature T1 (about 120° C.). When the temperature of the heat medium on the piping passage is higher than the film formation temperature T1, the first heat exchanger 29A receives a feedback signal that decreases the temperature of the heat medium. The heat medium held at the temperature near the film formation temperature T1 cools the lid 10b and the shower plate 20, which have been heated to high temperatures by the catalyst wire 30 that has been heated to 1700° C. to 2000° C. in the film formation process. This keeps the temperature in the film-forming chamber 11 substantially constant and reduces the process variations. When the first heat exchanger 29A for cooling the heat medium is driven, the second heat exchanger 29B is not driven, and only allows passage of the heat medium.

The second heat exchanger 29B heats the heat medium, whereas the first heat exchanger 29A cools the heat medium. The second heat exchanger 29B may have any structure and may, for example, include a conductive plate that is set in contact with the piping passage, through which the heat medium flows, to heat the heat medium with the heat released from the conductive plate through the piping passage. The second heat exchanger 29B also receives a feedback signal from the temperature controller 26c, and controls the temperature of the heat medium based on the feedback signal. In the cleaning process, for example, the heat medium is controlled to a temperature T2 for cleaning. When the temperature of the heat medium on the piping passage is lower than the cleaning temperature T2, the second heat exchanger 29B receives a feedback signal that increases the temperature of the heat medium. The heat medium adjusted to near the cleaning temperature T2 increases the temperature in the film-forming chamber 11 to a temperature suitable for cleaning. The first heat exchanger 29A is not driven when the second heat exchanger 29B for heating the heat medium is being driven.

The temperature controller 26c receives a temperature detection signal from the temperature sensor S1, which is arranged in the chamber 10, and determines whether or not the film-forming chamber 11 is maintained at a target temperature set for each process. When the temperature detected by the temperature sensor S1 differs from the target temperature by a predetermined temperature or more, the temperature controller 26c controls the heat exchangers 29A and 29B and the heaters 10h and 36 to control the temperature in the film-forming chamber 11 accordingly. In the present embodiment, the temperature adjustment mechanism 26 and the heaters 10h and 36 each form an example of a temperature adjustment unit.

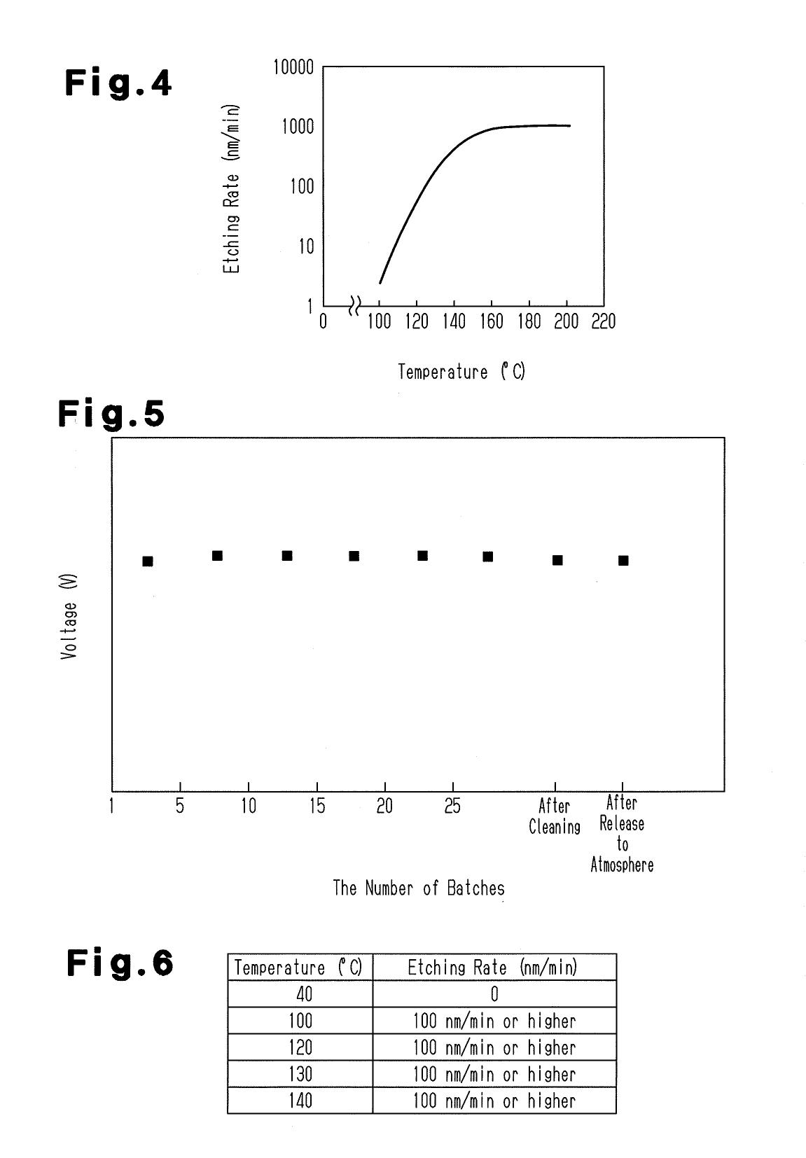

To remove the TiN film formation residue in the cleaning process, it is preferable to adjust the temperature in the film-forming chamber 11 to a temperature that thermally decomposes the cleaning gas, decreases the rate of reaction between at least the decomposed gas and the catalyst wire 30, and does not deteriorate the catalyst wire 30 even when the cleaning is repeated multiple times. FIG. 4 shows the correlation between the etching rate and the temperature in the film-forming chamber 11 when a TiN film is etched by ClF₃. In this example, 200 sccm of ClF₃ and 200 sccm of Ar gas are supplied to the film-forming chamber 11. The pressure is set to 667 Pa.

An increase in the temperature of the heat medium increases the temperature of the film-forming chamber 11. The TiN film is etched by the ClF₃ gas at 100° C. or greater temperatures in the film-forming chamber 11. The rate of etching increases as the temperature of the film-forming chamber 11 increases to approximately 100° C. to 160° C. When the temperature of the film-forming chamber 11 exceeds 160° C., the rate of etching converges at approximately 1000 nm/min. Thus, the temperature in the chamber 10, or specifically the film-forming chamber 11, is preferably 100° C. or greater. When the temperature exceeds 200° C., the seal 10c deteriorates at a faster rate. At temperatures exceeding 200° C., few catalysts can be supplied to the temperature adjustment mechanism 26 while maintained in liquid form. Thus, it is preferable that the cleaning temperature T2 of the heat medium be from 100° C. or higher to 200° C. or lower. An efficient rate of etching in the process is 100 nm/min or greater. The temperature of the heat medium that achieves this etching rate is about 120° C. It is thus more preferable that the target temperature in the cleaning process be from 120° C. or higher to 160° C. or lower.

FIG. 6 shows the correlation between the etching rate and the temperature in the film-forming chamber 11 when a TaN thin film having a thickness of 100 nm is etched by ClF₃. The etching is performed under the same conditions as for the TiN film. The results show that the TaN thin film was etched only slightly at a temperature of 40° C. in the film-forming chamber 11, whereas at 100° C. or higher temperatures, the TaN thin film was etched until the underlying Si layer was exposed. It is thus preferable that the temperature be 100° C. or higher to 200° C. or less for the TaN thin film.

For stable circulation in the temperature adjustment mechanism 26, the heat medium is preferably liquid at the cleaning temperature T2. Water used as the heat medium would not be circulated in a stable manner. It is preferable that the heat medium is a fluorinated material or a perfluoropolyether having a boiling point by of 150° C. or higher, such as Galden HT (registered trademark). It is also preferable that the heat medium is alkyl diphenyl or silicone oil. The boiling point by is higher than the target temperature of the film-forming chamber 11.

Film Formation Process

A process for forming a thin film of TiN, which is an example of the film formation process, will now be described. First, the pump (not shown) connected to the discharge passage 12b is driven to evacuate the film-forming chamber 11 to a predetermined vacuum degree. The substrate S is transported from outside through a gate valve (not shown), which is connected to the film-forming apparatus 1, and set on the substrate stage 35. The electrostatic chuck (not shown) is driven to attract the substrate S.

The gate valve is closed, and the pump is driven again to evacuate the film-forming chamber 11. Under the control of the control unit 1C, the constant current supply 31 supplies the catalyst wire 30 with current. When supplied with current, the catalyst wire 30 generates heat. The temperature of the catalyst wire 30 reaches 1700° C. to 2000° C.

The heater 10h arranged in the chamber 10 is energized so that the heater 10h is heated to, for example, approximately 120° C. The heater 36 arranged in the substrate stage 35 is also energized and heated to, for example, approximately 120° C.

To maintain the heat medium at the film formation temperature T1, the temperature controller 26c drives the first heat exchanger 29A or the second heat exchanger 29B. In the present embodiment, the film formation temperature T1 is set at 120° C. When, for example, the temperature of the heat medium is lower than the film formation temperature T1, the second heat exchanger 29B is driven to increase the temperature of the heat medium. When the temperature of the heat medium is higher than the film formation temperature T1, the first heat exchanger 29A is driven to decrease the temperature of the heat medium. The heat medium reaching the film formation temperature T1 cools the lid 10b of the chamber 10, the shower plate 20, and other components that have been heated as the catalyst wire 30 generates heat, and maintains the components at an equilibrium temperature of approximately 120° C.

When the catalyst wire 30 and the heaters 10h and 36 reach the above temperature, the film-forming gas supply system 13 is driven to supply film-forming gas, such as TiCl₄ and NH₃, into the film-forming chamber 11 through the gas supply passage 10e. Among the film-forming gases supplied into the film-forming chamber 11, the NH₃ gas contacts the catalyst wire 30, which has been heated to a high temperature. This decomposes the NH₃ gas and generates radical species. The radical species accelerate a radical chain reaction with TiCl₄ and ultimately form film formation species. The film formation species are deposited onto the surface of the substrate S, while diffusing in the film-forming chamber. The deposition forms a thin film of TiN. The intermediate products produced from the radical reaction as well as the film formation species diffused in the film-forming chamber 11 collect on the walls and the like of the chamber 10 and forms film formation residue of TiN. The catalyst wire 30 is heated to high temperatures of 1700° C. or higher. Thus, the film-forming gas decomposes immediately after contacting the catalyst wire 30 and diffuses in the film-forming chamber 11, without collecting on the surface of the catalyst wire 30.

When the film formation is completed, the film-forming gas supply system 13 stops supplying the film-forming gas, and the electrostatic chuck is deactivated. The substrate S is transported out of the chamber through the gate valve. This completes the film formation process for a single batch.

Cleaning Process

The film formation process is repeated for a plurality of batches. When the number of batches reaches a predetermined number, the cleaning process is performed. In the present embodiment, ClF₃ gas and Ar gas are used as the cleaning gas. The target temperature of the film-forming chamber 11 is set at 130° C.

First, the above pump is driven to discharge the film-forming gas supplied in the film formation process. When the film-forming chamber 11 is evacuated to a predetermined vacuum degree, the control unit 1C stops energizing the catalyst wire 30 and de-energizes the catalyst wire 30. When de-energized, the catalyst wire 30 cools rapidly to substantially the same temperature as the temperature in the film-forming chamber 11. The discharging of gas and the de-energizing of the catalyst wire 30 may be performed in the reversed order.

The heater 10h arranged in the chamber 10 is energized so that the heater 10h is heated to a temperature (e.g., 130° C.) near the target temperature, and the heater 36 in the substrate stage 35 is also maintained at a temperature near the temperature of the heater 10h. The temperature of the heaters 10h and 35 is set in accordance with the target temperature of the film-forming chamber 11, and is preferably from 100° C. or higher to 200° C. or lower.

The temperature controller 26c further controls the heat medium to, for example, 130° C., which is the cleaning temperature T2 set in the present embodiment. This maintains the temperature in the film-forming chamber 11 at around 130° C. In the present embodiment, the heat medium is near 120° C., which is the film formation temperature T1, after the film formation process. Thus, to heat the heat medium to the cleaning temperature T2, the temperature controller 26c drives the second heat exchanger 29B and heats the heat medium.

The temperature controller 26c uses the temperature sensor S1 arranged in the chamber to determine whether or not the temperature in the film-forming chamber 11 is maintained near the target temperature. When the temperature detected by the temperature sensor S1 is higher than the target temperature by a predetermined temperature, the temperature controller 26c controls the first heat exchanger 29A to decrease the temperature of the heat medium or outputs a signal for deactivating at least one of the heaters 10h and 36 to the control unit 1C. When the detected temperature is lower than the target temperature by a predetermined temperature, the temperature controller 26c controls the second heat exchanger 29B to increase the temperature of the heat medium. In this manner, the temperature controller 26c performs feedback control to maintain the temperature in the film-forming chamber 11 at around 130° C.

When the film-forming chamber 11 is held at around 130° C., the control unit 1C drives the cleaning gas supply system 21 to supply the ClF₃ gas and the Ar gas into the film-forming chamber 11 through the shower plate 20. It is preferable that the flow amount of ClF₃ gas be from 100 sccm or higher to 500 sccm or lower. When the gas flow amount is lower than 100 sccm, the film formation residues are etched by the ClF₃ gas at a low etching rate. When the gas flow amount is higher than 500 sccm, the etching consumes more gas without increasing the etching rate. The inert gas, which may be the Ar gas, is used to adjust the pressure. Thus, it is preferable that the flow amount of the inert gas be from 0 sccm or higher to 500 sccm or lower. The pressure is preferably 665 Pa or greater.

The film-forming chamber 11 is held at approximately 130° C. Thus, the ClF₃ gas decomposes by absorbing thermal energy in the film-forming chamber 11. The thermally decomposed gas reacts with the film formation residues collected on the walls and the like of the chamber and generates reaction products, such as TiF and TiCl. The reaction products diffuse in the film-forming chamber 11. When the pump is driven, the reaction products are discharged out of the film-forming chamber 11 through the discharge passage 12b.

The catalyst wire 30 slightly reacts with the cleaning gas. Thus, the catalyst wire 30 is slightly corroded when the cleaning process is performed a number of times. FIG. 5 shows voltage changes of the catalyst wire 30 before and after the cleaning process. The catalyst wire 30 is supplied with a constant current (e.g., 14.2 A). Thus, when the catalyst wire 30 corrodes, the resistance of the current increases and changes the voltage applied to the catalyst wire 30. The results show no changes in the voltage of the catalyst wire 30 from the first to 25th batches. The voltage measured after the cleaning process for the 25th batch has no difference from the voltage measured before the cleaning process. In other words, when the ClF₃ gas is supplied at a temperature of 120° C. or higher, the thermally decomposed ClF₃ gas reacts mainly with TiN. Thus, the tungsten catalyst wire 30 is slightly corroded. It is assumed that this is because the thermally decomposed ClF₃ gas reacts mainly with TiN in the above temperature range, and reaction of the ClF₃ gas with tungsten is hindered. Thus, the cleaning process may be performed without diffusing the molecules of the catalyst wire 30 into the film-forming chamber 11 and without corroding the catalyst wire 30.

The above embodiment has the advantages described below.

(1) In the above embodiment, the film-forming apparatus 1 includes the film-forming gas supply system 13, which supplies the film-forming gas for forming a thin film of TiN, and the cleaning gas supply system 21, which supplies the cleaning gas including ClF₃, and the control unit 1C, which sets the catalyst wire 30 in a non-heated state in the cleaning process that discharges film formation residues adhering to inner portions of the chamber 10. The film-forming apparatus 1 further includes the temperature adjustment mechanism 26, which maintains the temperature in the chamber 10 at the target temperature (100° C. or higher to 200° C. or less), and the discharge passage 12b, which discharges the reaction products resulting from reaction between the film formation residues and the cleaning gas. More specifically, the temperature in the chamber 10 is adjusted to the target temperature to reduce corrosion of the catalyst wire 30 caused by the cleaning gas. Also, the adjustment of the temperature in the chamber 10 to the target temperature allows the cleaning gas to thermally decompose in a spontaneous manner without absorbing heat from the catalyst wire 30. This obviates the need to heat the catalyst wire 30 to high temperatures that would diffuse metal atoms. Thus, the atoms of the catalyst wire 30 are prevented from being diffused as impurities that would contaminate thin films. This structure reduces corrosion of the catalyst wire 30 in the cleaning process while preventing a decrease in the yield. The cleaning process only sets the catalyst wire 30 in a non-heated state and adjusts the temperature of the chamber 10. This structure eliminates the need for a mechanism that moves the catalyst wire 30, and prevents the apparatus from being complicated.

(2) In the above embodiment, the temperature adjustment mechanism 26 includes a heat medium that has at least a boiling point that is higher than or equal to the target temperature, and exchanges heat between the heat medium and the chamber 10. The temperature adjustment mechanism 26 includes the first heat exchanger 29A, which cools the heat medium in the film formation process, and the second heat exchanger 29B, which heats the heat medium to heat the chamber 10 in the cleaning process. This structure integrates the cooling mechanism for cooling the chamber and the heating mechanism for heating the chamber 10. Thus, enlargement of the apparatus is suppressed.

(3) In the above embodiment, the seal 10c for hermetically sealing the film-forming chamber 11 is formed from perfluoro rubber (or perfluoroelastomer). This allows the ClF₃ gas to be used in the cleaning while reducing the seal corrosion speed.

The above embodiment may be modified in the following forms.

In the above embodiment, the temperature adjustment mechanism 26 cools and heats the chamber 10 and other components. Alternatively, a cooling unit and a heating unit may be separately arranged. For example, a section of the temperature adjustment mechanism 26 above the shower plate 20 may function solely as the cooling unit, whereas the heater 10h arranged in the chamber 10 or the heater 36 may function as the heating unit. The heat medium used in the temperature adjustment mechanism 26 may be a stable gas.

In the above embodiment, the film formation temperature T1 for the heat medium in the film formation process is lower than the cleaning temperature T2 used in the cleaning process. Alternatively, the film formation temperature T1 may be higher than the cleaning temperature T2. In this case, heat energy stored in the heat medium in the film formation process may be used to radiate the heat stored in the heat medium in the cleaning process performed after the film formation process to maintain the temperature of the film-forming chamber 11 at the cleaning temperature T2.

In the above embodiment, the cooling unit and the heating unit of the temperature adjustment mechanism 26 are arranged in the heat medium pipe 26a. Alternatively, the cooling unit and the heating unit may be arranged in the heat medium reservoir 27. Although the temperature sensor S2 is arranged in the piping passage of the heat medium pipe 26a, the temperature sensor S2 may be arranged in the heat medium reservoir 27.

Although the film-forming apparatus 1 forms thin films of TiN in the above embodiment, the film-forming apparatus 1 may form thin films including at least one of TaN, WF₆, HfCl₄, Ti, Ta, Tr, Pt, Ru, Si, SiN, SiC, and Ge. The film-forming apparatus may also form organic thin films. In this case as well, a cleaning gas including ClF₃ can be used to remove the film formation residues.

Although the film-forming apparatus of the present invention is a catalytic CVD apparatus in the above embodiment, the film-forming apparatus may be a hot-wire apparatus including a hot wire that decomposes a film-forming gas with a hot wire that causes no catalytic actions. The hot-wire apparatus has the same structure as the catalytic CVD apparatus.

1. A film-forming apparatus including a heat generator exposed to a film-forming gas drawn into a chamber to generate film formation species, the apparatus comprising:
a film-forming gas supply system that supplies the film-forming gas into the chamber;
a control unit that sets the heat generator in a non-heated state during a cleaning process that discharges a film formation residue from the chamber;
a cleaning gas supplying system that supplies a cleaning gas including ClF₃ into the chamber;
a temperature adjustment unit that adjusts the chamber to a target temperature from 100° C. or higher to 200° C. or less in the cleaning process; and
a discharge system that discharges a reaction product produced by a reaction between the film formation residue and the cleaning gas from the chamber.

2. The film-forming apparatus according to claim 1, wherein
the temperature adjustment unit includes a temperature adjustment mechanism that uses a heat medium having a boiling point higher than or equal to the target temperature to exchange heat between the heat medium and the chamber, and
the temperature adjustment mechanism includes a cooling unit, which cools the heat medium in a film formation process, and a heating unit, which heats the heat medium in the cleaning process when the heat medium has a lower temperature than the target temperature.

3. The film-forming apparatus according to claim 1, wherein the film-forming gas supply system supplies the film-forming gas to form a thin film, which includes at least one of TiN, TaN, WF_{C}, HfCl₄, Ti, Ta, Tr, Pt, Ru, Si, SiN, SiC, and Ge, or to form an organic thin film.

4. The film-forming apparatus according to claim 1, further comprising a seal that hermetically seals the chamber, wherein the seal is formed from perfluoro rubber or perfluoroelastomer.

5. A method for cleaning a film-forming apparatus, wherein the film-forming apparatus performs a film formation process for exposing a heat generator arranged in a chamber to a film-forming gas to generate film formation species and form a thin film on a substrate and then performs a cleaning process to remove a film formation residue from the chamber, the method comprising:
setting the heat generator in a non-heated state;
adjusting the chamber to a target temperature from 100° C. or higher to 200° C. or lower; and
supplying a cleaning gas including ClF₃ into the chamber so that the cleaning gas reacts with the film formation residue in the chamber and discharging a reaction product produced by a reaction between the cleaning gas and the film formation residue.
